(19) United States
(12) Patent Application Publication
(10) Pub. No.: US 2026/0188622 A1
(43) Pub. Date: Jul. 2, 2026

(54) CONTROLLING GAS FLOWS IN PROCESSING TOOL

(71) Applicant: Lam Research Corporation, Fremont, CA (US)

(72) Inventors: Michael Philip ROBERTS, Tigard, OR (US); Gopinath BHIMARASETTI, Portland, OR (US); John Michael WILTSE, Lake Oswego, OR (US); Adam FISHER, Portland, OR (US); William SCHLOSSER, Tigard, OR (US); Steven Payonk LETOURNEAU, Portland, OR (US); Nathaniel Elba RICHEY, Tualatin, OR (US); Hyeongeu KIM, Tualatin, OR (US); Andrew Kenichi DUVALL, Portland, OR (US); Tongtong GUO, Beaverton, OR (US); Michael William HOBERNICHT, Portland, OR (US)

(21) Appl. No.: 19/127,661

(22) PCT Filed: Nov. 2, 2023
(86) PCT No.: PCT/US2023/078561

§ 371 Date: May 6, 2025

Related U.S. Application Data
(60) Provisional application No. 63/387,057, filed on Dec. 12, 2022.

(51) Int. Cl. H01J 37/32

(52) U.S. Cl. CPC H01J 37/32449; H01J 37/32357; H01J 37/32807; H01J 37/32862; H01J 2237/335

(57) ABSTRACT

One example provides a processing tool comprising a processing chamber and a remote plasma generator (RPG) fluidly connected to the processing chamber. The processing tool further comprises an RPG gas supply system for mixing and delivering gases to the RPG. The RPG gas supply system comprises a first RPG gas supply line for delivering a first gas at a first, lower flow rate to the RPG, a second RPG gas supply line for delivering a second gas at a second, higher flow rate to the RPG, a junction connecting the first RPG gas supply line and the second RPG gas supply line, an orifice in the first RPG gas supply line, a divert valve on the second RPG gas supply line for diverting the flow away from the RPG and a common RPG gas supply line connecting the junction to the RPG.

### BACKGROUND

Semiconductor device fabrication processes may involve many steps of material deposition, patterning and removal to form integrated circuits on substrates. One method of deposition is atomic layer deposition (ALD). Atomic layer deposition is a process in which a film is formed on a substrate in one or more individual layers. The formation of each film layer comprises sequentially adsorbing a precursor to a substrate and then chemically transforming the adsorbed precursor with a reactant.

### SUMMARY

This Summary is provided to introduce a selection of concepts in a simplified form that are further described below in the Detailed Description. This Summary is not intended to identify key features or essential features of the claimed subject matter, nor is it intended to be used to limit the scope of the claimed subject matter. Furthermore, the claimed subject matter is not limited to implementations that solve any or all disadvantages noted in any part of this disclosure.

Examples are disclosed that relate to controlling processing gas flows in a processing tool. One example provides a processing tool comprising a processing chamber and a remote plasma generator (RPG) fluidly connected to the processing chamber. The processing tool further comprises an RPG gas supply system for mixing and delivering gases to the RPG. The RPG gas supply system comprises a first RPG gas line for delivering a first gas at a first flow rate to the RPG and a second RPG gas line for delivering a second gas at a second flow rate to the RPG, the second flow rate higher than the first flow rate. The RPG gas supply system further comprises a junction connecting the first RPG gas line and the second RPG gas line. The RPG gas supply system further comprises an orifice in the first RPG gas line and a divert valve on the second RPG gas line for diverting a flow away from the RPG. The RPG gas supply system additionally comprises a common RPG gas line connecting the junction to the RPG.

In some such examples, the second RPG gas line alternatively or additionally comprises a mass flow controller upstream of the junction connecting the first RPG gas line and the second RPG gas line.

In some such examples, the first RPG gas line is alternatively or additionally connected to a hydrogen gas source and a nitrogen gas source.

In some such examples, the second RPG gas line is alternatively or additionally connected to a nitrogen gas source.

In some such examples, the processing chamber alternatively or additionally comprises a showerhead and a pedestal, and the showerhead comprises a showerhead purge gas outlet disposed adjacent to a perimeter of the showerhead.

In some such examples, the processing tool alternatively or additionally comprises a controller configured to control a flow of inert gas through the showerhead purge gas outlet during a deposition process.

In some such examples, the processing tool alternatively or additionally comprises a pedestal and a below-pedestal purge system. The below-pedestal purge system comprises one or more openings to flow a purge gas into the processing chamber beneath the pedestal.

In some such examples, the processing tool alternatively or additionally comprises a controller configured to control a flow of inert gas through the below-pedestal purge system during a deposition process.

In some such examples, the processing tool alternatively or additionally comprises a flow over vapor (FOV) chemical supply system for delivering a processing chemical to the processing chamber. The FOV chemical supply system comprises a processing chemical delivery gas line comprising an inner diameter in a range of 0.110-0.430 inch.

Another example provides a processing tool comprising a processing chamber. The processing chamber comprises a pedestal well. The processing tool further comprises a pedestal positioned at least partially within the pedestal well and a below-pedestal purge system configured to introduce a flow of a purge gas into the pedestal well beneath the pedestal.

In some such examples, the below-pedestal purge system alternatively or additionally comprises a below-pedestal plenum arranged at least partially around a pedestal support of the pedestal. The below-pedestal plenum comprises one or more openings to flow the purge gas into the processing chamber from beneath the pedestal.

In some such examples, the below-pedestal plenum alternatively or additionally is annular in shape.

In some such examples, the below-pedestal plenum alternatively or additionally comprises a plurality of openings.

In some such examples, the below-pedestal plenum alternatively or additionally is additively manufactured.

In some such examples, the processing tool alternatively or additionally comprises a showerhead. The showerhead comprises a showerhead purge gas outlet.

Another example provides a method of modifying a processing tool. The processing tool comprises a processing chamber and a FOV chemical supply system for delivering a processing chemical to the processing chamber. The FOV chemical supply system comprises a gas line for processing chemical delivery to the processing chamber. The method comprises replacing an initial gas line with a replacement gas line. The replacement gas line comprises a smaller inner diameter than the initial gas line. The replacement gas line decreases a time that elapses between opening a FOV chemical supply system valve and FOV chemical reaching the processing chamber. The method further comprises replacing at least one other FOV chemical supply system component to reduce a dead volume in the FOV chemical supply system.

In some such examples, the initial gas line comprises an inner diameter of greater than or equal to 0.305 inch, and the replacement gas line comprises an inner diameter in the range of 0.110-0.430 inch.

In some such examples, replacing at least one other FOV chemical supply system component alternatively or additionally comprises shortening a valve connection.

In some such examples, replacing at least one other FOV chemical supply system component alternatively or additionally comprises removing a charge volume hardware.

In some such examples, replacing at least one other FOV chemical supply system component alternatively or additionally comprises replacing a first valve manifold with a second valve manifold with a reduced dead volume.

### BRIEF DESCRIPTION OF THE DRAWINGS

FIG. 1 shows a block diagram of an example processing tool.

FIG. 2 schematically shows an example remote plasma generator (RPG) gas manifold for selectively diverting a purge gas to an exhaust system.

FIGS. 3A-3B schematically show a divert valve in an RPG gas manifold.

FIGS. 4A-4B schematically show example effects of the divert valve of FIG. 3 on the flow rate into and out of an example processing chamber.

FIG. 5A schematically shows an example initial flow over vapor (FOV) gas line.

FIG. 5B schematically shows an example replacement FOV gas line.

FIG. 6 shows a graph that illustrates an example effect of the modification of FIGS. 5A-5B on a precursor flow rate into an example processing chamber.

FIG. 7 schematically shows an example showerhead comprising a purge gas outlet.

FIG. 8 schematically shows an example below-pedestal purge system.

FIG. 9 schematically shows another example below-pedestal purge system.

FIG. 10 shows a flow diagram illustrating an example process for modifying a processing tool to reduce dead volume in a FOV chemical supply system.

### DETAILED DESCRIPTION

The term “atomic layer deposition” (ALD) generally represents a process in which a film is formed on a substrate in one or more individual layers by sequentially adsorbing a precursor to a substrate and then chemically transforming the adsorbed precursor to form a film layer. Examples of ALD processes comprise plasma-enhanced ALD (PEALD) and thermal ALD (TALD). PEALD and TALD respectively utilize a plasma of a reactive gas and heat to facilitate a chemical conversion of a precursor adsorbed to a substrate to a film on the substrate.

The term “below-pedestal purge system” generally represents a system for introducing a controlled flow of a purge gas into a chamber at a location below a pedestal in a processing chamber.

The term “charge volume hardware” generally represents an open volume in the gas lines for the purpose of increasing an internal volume of a processing gas distribution system. For example, charge volume hardware may comprise a tube section for collecting and subsequently releasing gas volumes during the pressure changes of a process cycle.

The term “dead volume” generally represents a volume in a fluid line that does not have an inlet and an outlet but rather a single opening. A dead volume can exist temporarily. For example, a valve may comprise a stem that defines dead volume when the valve is closed, but not when the valve is open.

The term “divert valve” generally represents a valve that can be switched between directing a flow to a processing chamber and directing the flow to an exhaust system.

The term “flow over vapor” (FOV) may generally refer to delivery of a liquid-phase precursor to a processing chamber by flowing a carrier gas over a surface of the liquid-phase precursor to draw precursor vapor with the flow of the carrier gas.

The term “gas supply system” generally represents a system of pipes, fittings, joints, valves, mass flow controllers, and/or other components used to deliver a gas in a controlled manner from a point of origin to a destination point.

The term “mass flow controller” (MFC) generally represents a device for controlling the mass flow rate of a fluid. Mass flow controllers compensate for density such that a constant mass flow rate is maintained at a given set point.

The term “pedestal” generally represents a structure on which a substrate is positioned in a processing chamber during processing.

The term “pedestal stem” generally represents a support structure that holds a pedestal in position within a processing chamber above a base of a processing chamber.

The term “pedestal well” generally represents a volume of space in a processing chamber that is below a pedestal and that is recessed compared to an adjacent bottom surface in the processing chamber. A pedestal stem may be located in a pedestal well.

The term “plasma” generally represents a gas-phase composition comprising cations and free electrons.

The term “processing chamber” generally represents an enclosure in which chemical and/or physical processes are performed on substrates. The pressure, temperature and atmospheric composition within a processing chamber may be controllable to perform the chemical and/or physical processes.

The term “processing tool” generally represents a machine including a processing chamber and other hardware configured to enable ALD to be carried out on a substrate located in the processing chamber.

The terms “purge” and variants thereof generally represent processes in which unwanted species are removed from a processing chamber.

The term “remote plasma” generally represents a plasma used to produce chemical species at a location remote from a substrate being processed with the chemical species.

The term “remote plasma generator” (RPG) generally represents a combination of components that can be used to form a remote plasma.

The term “showerhead” generally represents a processing chemical outlet comprising a plurality of holes distributed across an area.

The term “substrate” generally represents any object on which a film can be deposited.

The term “manifold” generally represents a structure that allows for a processing gas to be distributed from one line into multiple lines, or gathered from multiple lines into one line.

As mentioned above, ALD involves forming a film on a substrate in a processing chamber in one or more individual film layers by sequentially adsorbing a first precursor to a substrate and then chemically transforming the adsorbed precursor to form a film layer. A reactant may be used in the chemical transformation step. In some examples, the reactant used for the chemical transformation may be introduced into a remote plasma generator (RPG). The RPG converts the reactant to reactive species. The reactive species are introduced into the processing chamber. The reactive species in the processing chamber react with the precursor adsorbed on the substrate to cause the chemical transformation.

An ALD process involves providing alternating flows of the precursor and the reactant into the processing chamber. Purge steps are used between introducing the precursor into the processing chamber and introducing reactive species from the RPG into the processing chamber. However, flows of the first precursor and the reactive species from the RPG take time to stabilize and reach their respective setpoints. Where mass flow controllers are used to control gas flows, the ramp up and ramp down times of the mass flow controller may comprise a significant fraction of the ALD cycle time.

Decreasing the time utilized to switch between flows of the first precursor and reactive species from the RPG may decrease an ALD cycle time. This may help to achieve higher throughput. Accordingly, examples are disclosed that relate to configuring a processing tool for switching gas flows in an efficient manner. One example provides a processing tool. The processing tool comprises a processing chamber. The processing tool further comprises a remote plasma generator (RPG) fluidly connected to the processing chamber. The processing tool additionally comprises an RPG gas supply system for mixing and delivering gases to the RPG. The RPG gas supply system comprises a first RPG gas line for delivering a first gas at a first flow rate to the RPG, and a second RPG gas line for delivering a second gas at a second flow rate to the RPG, the second flow rate higher than the first flow rate. In some examples, the first RPG gas line may deliver a low flow of nitrogen with a concentration of hydrogen as a precursor gas mixture for forming nitrogen-containing radical species in the RPG. The second RPG gas line may deliver a higher flow of nitrogen for purging the processing chamber. The RPG gas supply system further comprises a junction where the first RPG gas line and second RPG gas line meet. The RPG gas supply system further comprises an orifice in the first RPG gas line, a divert valve on the second RPG gas line for selectively diverting the flow in the second RPG gas line away from the RPG, and a common RPG gas line connecting the junction to the RPG.

If purge gas flow in the second RPG gas line were ramped up and down by controlling a mass flow controller, significant time may be occupied by the ramp up and ramp down processes in each cycle. However, the divert valve in the second gas line allows purge gas flow in the second RPG gas line to be quickly directed to the RPG for a purge process, and then quickly diverted to exhaust for a reactant deposition cycle. Gas flow in the first RPG gas line may remain at a set, lower level. The orifice in the first RPG gas line prevents back streaming when the divert value in the second RPG line is switched to provide purge gas to the RPG. This helps, for example, to prevent disruption to the flow of hydrogen that otherwise may occur when switching the divert valve back to operating the divert valve to direct the purge gas to the exhaust. As such, this helps to stabilize gas flows more quickly between ALD cycles.

Another example provides a processing tool comprising a processing chamber comprising a pedestal well, a pedestal positioned at least partially within the pedestal well, and a below-pedestal purge system configured to introduce a flow of a purge gas into the pedestal well beneath the pedestal. Flow of the purge gas from the pedestal well may help to lessen the migration of processing gases into the pedestal well during a precursor adsorption and during a chemical transformation process. The flow of purge gas from beneath the pedestal may help to reduce purge times when switching gas flows. The below-pedestal purge system also may help to increase a residence time of precursor gas and/or reactive species over the substrate surface, as explained in more detail below. These effects may help to increase throughput.

Further, an ALD tool may be retrofit to decrease an amount of time a precursor charge takes to reach the processing chamber. For example, an inner diameter of one or more gas lines in the ALD tool may be reduced to increase a flow velocity within the one or more gas lines. Thus, another disclosed example provides a method of modifying a processing tool. The processing tool comprises a processing chamber and a flow over vapor (FOV) chemical supply system for delivering a processing chemical to the processing chamber. The FOV chemical supply system comprises a gas line for processing chemical delivery to the processing chamber. The method comprises replacing an initial gas line with a replacement gas line, the initial gas line comprising an inner diameter of greater than or equal to 0.305 inch, and the replacement gas line comprising an inner diameter in the range of 0.110-0.430 inch. Replacing the initial gas line with the replacement gas line decreases a time that elapses between opening a FOV chemical supply system valve and FOV chemical reaching the processing chamber. The method further comprises replacing at least one other FOV chemical supply system component to reduce an amount of dead volume in the FOV chemical supply system.

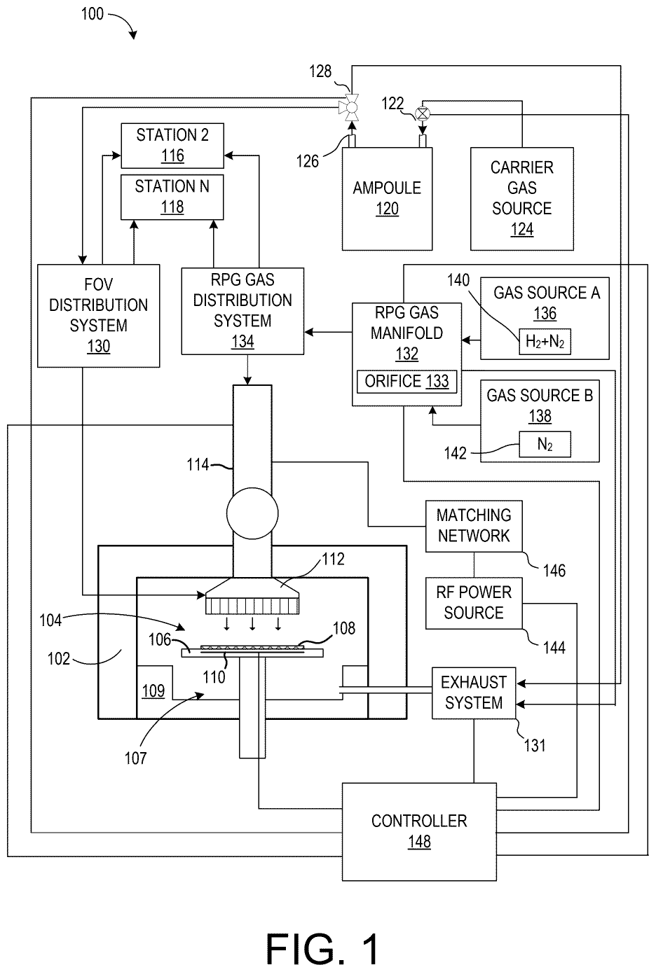

FIG. 1 shows a block diagram of an example processing tool 100 for performing material deposition. Processing tool 100 comprises a processing chamber 102. The processing chamber 102 comprises a processing station 104. Processing station 104 comprises a pedestal 106 for supporting a substrate 108. Pedestal 106 is positioned at least partially within a pedestal well 107 that is recessed from surrounding areas of a processing chamber base 109. Pedestal 106 further may include a substrate heater 110 configured to heat substrate 108.

Processing station 104 further comprises a processing gas outlet 112. In some examples, processing gas outlet 112 may comprise a nozzle, showerhead, or other apparatus for introducing a processing gas into processing station 104. Pedestal 106 can be raised and lowered to adjust the spacing between substrate 108 and processing gas outlet 112. In some examples, processing gas outlet 112 may comprise a heater.

Processing gas outlet 112 is fluidly connected to a remote plasma generator (RPG) 114. RPG 114 is configured to generate radical species from a gas-phase precursor. The radical species formed by RPG 114 can react with a precursor adsorbed to a surface of substrate to form a layer of a film in an ALD process. RPG 114 is discussed in more detail below.

In some examples, processing chamber 102 may comprise a plurality of processing stations. A plurality of processing stations is shown in FIG. 1 as processing station 2 116 through processing station N 118. In this example, N is an integer equal to or greater than zero. While shown outside of processing chamber 102 in this schematic depiction, processing station 2 116 and processing station N 118 each can be located within processing chamber 102. Each of processing station 2 116 and processing station N 118 comprises a substrate holder, a substrate heater, a processing gas outlet, an RPG, and other hardware for processing a substrate within processing chamber 102. In other examples, a processing chamber may comprise a single processing station.

Processing tool 100 further comprises an ampoule 120 configured to hold a liquid phase precursor comprising a vapor pressure. Ampoule 120 comprises a flow-over vapor (FOV) gas inlet 122 for flowing a carrier gas from a carrier gas source 124 into ampoule 120. Example carrier gases include nitrogen and argon. Further example carrier gases include helium, neon, krypton, and xenon. FOV gas inlet 122 may include a mass flow controller (not shown) for controlling the flow of the carrier gas.

Ampoule 120 further comprises a FOV gas outlet 126 for flowing gas out of ampoule 120. When a carrier gas is flowed through ampoule 120, the carrier gas flows over the surface of the precursor and draws vapor of the precursor through FOV gas outlet 126. A valve 128 is controllable to direct an outflow from ampoule 120 to a FOV distribution system 130 or to an exhaust system 131. Exhaust system 131 is configured to remove gases from processing chamber 102. Exhaust system 131 may comprise any suitable components, including one or more pumps.

FOV distribution system 130 is configured to distribute precursor from ampoule 120 to processing stations 104, 116, 118. A portion of the gases from FOV distribution system 130 flows to processing station 104 and through the processing gas outlet 112 onto the substrate. Similar portions of the gases from FOV distribution system 130 also flow into each of processing station 2 116 and processing station N 118.

Processing tool 100 further comprises an RPG gas manifold 132 and an RPG gas distribution system 134. RPG gas manifold 132 is fluidly connected to one or more gas source(s) A 136 and one or more gas source(s) B 138. Gas source(s) A 136 can comprise a reactant gas or reactant gas mixture. Gas source(s) B 138 can comprise a purge gas or purge gas mixture. As such, gas source(s) A can be configured to flow the processing gas(es) at a first flow rate into RPG gas manifold 132. Further, gas source(s) B can be configured to flow purge gas(es) at a second flow rate into RPG gas manifold 132, the second flow rate higher than the first flow rate. In the depicted example, gas source(s) A 136 comprises a mixture of hydrogen and nitrogen at 140. Further, gas source(s) B 138 comprises nitrogen at 142. In other examples, any suitable gas or gas mixtures may be used for gas source(s) A 136 and/or gas source(s) B 138.

When RPG 114 is generating reactive species for an ALD process, gas source(s) A 136 but not gas source(s) B 138 may provide gas to RPG 114. During a purge process, gas source(s) A 136 and gas source(s) B 138 can provide gas to RPG 114. Thus, as described in more detail below, RPG gas manifold 132 valve can be provided to selectively direct gas from gas source(s) B to RPG gas manifold 132 or to exhaust system 131.

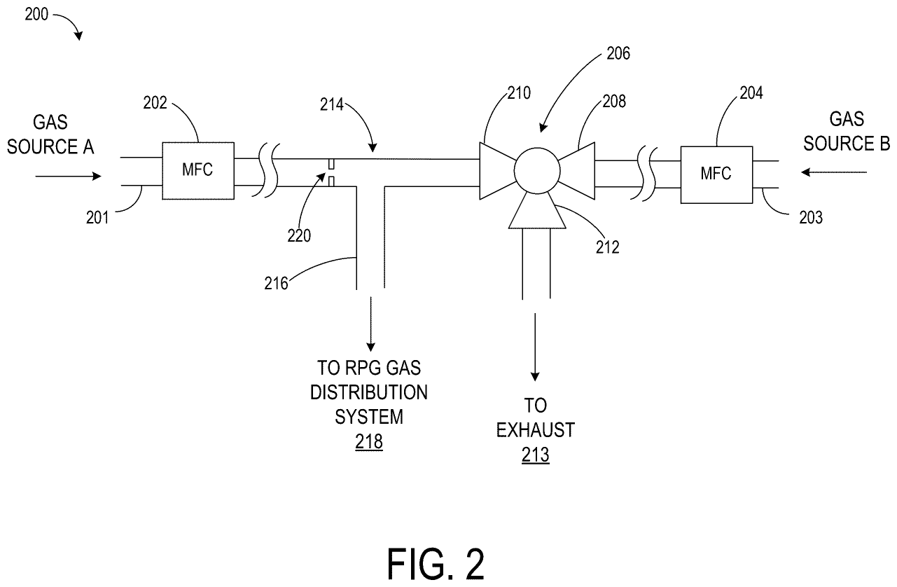

As described in more detail below, RPG gas manifold 132 comprises an orifice 133. The orifice 133 is configured to prevent the flow of gas from gas source(s) B 138 from causing hydrogen to backflow into gas source(s) A 136 when gas source(s) B 138 is switched from providing gas to exhaust system 131 to providing gas to RPG gas manifold 132. An example orifice is described in more detail below with regard to FIG. 2.

The gases from RPG gas manifold 132 are directed to RPG gas distribution system 134. RPG gas distribution system 134 is configured to distribute the gas between RPGs for different processing stations (e.g. RPG 114, and RPGs for processing station 2 116 and processing station N 118. During an ALD process, RPG 114 produces reactive species from gases introduced from gas source(s) A 136. The reactive species from RPG 114 are introduced to processing station 104 using processing gas outlet 112.

The processing tool 100 further comprises a radiofrequency power source 144 electrically connected to RPG 114. Processing tool 100 further comprises a matching network 146 for impedance matching of the radiofrequency power source 144. RPG 114 may comprise a capacitively coupled plasma generator or an inductively coupled plasma generator. In other examples, RPG may comprise a microwave plasma generator.

Radiofrequency power source 144 may be configured for any suitable frequency and power. Examples of suitable frequencies include 400 kHz, 13.56 MHz, 27 MHz, 60 Mz, and 90 MHz. Examples of suitable powers include powers between 50 W (watts) and 50 kW. In some examples, radiofrequency power source 144 may be configured to operate at a plurality of different frequencies and/or powers.

Controller 148 is operatively coupled to controllable components of processing tool 100. For example, controller 148 is operatively coupled to substrate heater 110, RPG 114, ampoule 120, exhaust system 131, RPG gas manifold 132, radiofrequency power source 144, and matching network 146. Controller 148 further may be operatively coupled to any other suitable component of processing tool 100. Controller 148 is configured to control various functions of processing tool 100 to perform an ALD process.

For example, controller 148 is configured to operate substrate heater 110 to heat a substrate. Controller 148 is also configured to control valve 128 to flow gas from ampoule 120 into the FOV distribution system 130 or direct it to exhaust system 131.

As further examples, controller 148 is also configured to control a divert valve in RPG gas manifold 132. Controller 148 may direct the flow from the RPG gas manifold 132 to the RPG gas distribution system 134 by switching the divert valve to flow into the RPG gas distribution system 134. Similarly, controller 148 may direct flow to the exhaust system 131 by switching the divert valve to flow to the exhaust system 131. Controller 148 is also configured to operate exhaust system 131 to remove gases from processing chamber 102.

FIG. 2 schematically shows an example RPG gas manifold 200. RPG gas manifold is an example of RPG gas manifold 132 of FIG. 1. RPG gas manifold 200 receives flows of gases from gas source A and gas source B. Gas from gas source A is conducted through a first RPG gas line 201. Gas from gas source B is conducted through a second RPG gas line 203. Each of gas source A and gas source B may comprise a single gas from a single source, or a mixture of gases from one or more sources. As mentioned above, in some examples, gas source A may comprise a mixture of hydrogen and nitrogen, and gas source B may comprise nitrogen.

Gas flow from gas source A is controlled by one or more mass flow controllers, here represented as mass flow controller 202. In some examples, a single mass flow controller 202 may be calibrated to flow a mixture of hydrogen and nitrogen. In other examples, separate mass flow controllers may be used for nitrogen and hydrogen. Further, flow from gas source B is controlled by one or more mass flow controllers, here represented as mass flow controller 204. Gas source B may be configured to provide nitrogen. As such, mass flow controller 204 is calibrated to flow nitrogen gas. In other examples, one or more purge gases other than nitrogen alternatively or additionally may be used.

A divert valve 206 is located downstream of mass flow controller 204. Divert valve 206 comprises an inlet 208, a first outlet 210, and a second outlet 212. When divert valve 206 is in a first state, gas from gas source(s) B is diverted to exhaust 213. Downstream of divert valve 206, second RPG gas line 203 is connected to a tee 214. First RPG gas line 201 also is connected to tee 214. A common RPG gas line 216 leads from tee 214 to RPG gas distribution system 218. RPG gas distribution system 218 is an example of the RPG gas distribution system 134 in FIG. 1.

When divert valve 206 is switched to a second state, gas from gas source B is directed to tee 214. As mentioned earlier, gas source(s) A may provide a relatively lower flow rate of a processing gas mixture than the flow rate of purge gas from gas source B. The differences in flow rates could potentially cause gas from gas source B to back stream into first RPG gas line 201. This can lead to concentration transients that delay gas stabilization in an ALD process. Thus, first RPG gas line 201 comprises an orifice 220 to help prevent such backflow by impeding the higher flow from gas source B into first RPG gas line 201. Orifice 220 can have any suitable configuration. In some examples, orifice 220 can be formed in a gas line gasket. In other examples, orifice 220 can comprise a separate structure from a gasket. Orifice 220 can be located any suitable distance upstream of tee 214 in the path of first RPG gas line 201. In some examples, orifice 220 can have a diameter within a range of 0.015 to 0.080 inch. In some such examples, orifice 220 can have a diameter within a range of 0.015 to 0.025 inch. In other such examples, the orifice 220 can have a diameter within a range of 0.050 to 0.080 inches. Orifices having diameters within these ranges can help to prevent hydrogen backflow in various implementations. In further examples, the orifice can have a size outside of these ranges.

The use of divert valve 206 to control purge gas flow from gas source B may enable faster stabilization of the purge gas flow to an RPG than the use of a mass flow controller to control purge gas flow.

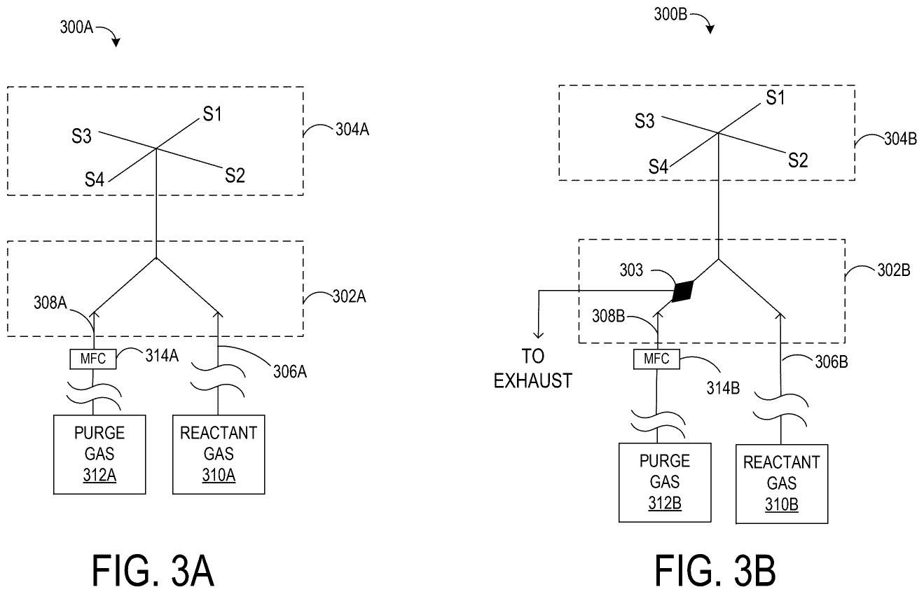

FIG. 3A schematically shows an RPG gas system 300A comprising an RPG gas manifold 302A without a divert valve. The term “RPG gas system” represents components that provide and control a flow of gas to an RPG. FIG. 3B schematically shows an RPG gas system 300B comprising an RPG gas manifold 302B with a divert valve 303. In FIG. 3A, S1, S2, S3 and S4 represent four processing stations in a processing chamber 304A. In FIGS. 3B, 3A, S1, S2, S3 and S4 represent four processing stations in a processing chamber 304B.

RPG gas system 300A of FIG. 3A comprises a first RPG gas line 306A and a second RPG gas line 308A. First RPG gas line 306A is configured to provide a flow of a reactant gas 310A. The reactant gas may comprise a gas mixture, such as hydrogen/nitrogen mixture. Second RPG gas line 308A is configured to provide a flow of a purge gas 312A. Nitrogen is an example purge gas. Flow of the purge gas during an ALD process is controlled by a mass flow controller 314A. Reactant gas flow also may be controlled by a mass flow controller (not shown) along first RPG gas line 306A.

RPG gas system 300B of FIG. 3B comprises a first RPG gas line 306B and a second RPG gas line 308B. First RPG gas line 306B is configured to provide a flow of a reactant gas 310B. The reactant gas may be a gas mixture, such as hydrogen/nitrogen mixture. Second RPG gas line 308B is configured to provide a flow of a purge gas 312B. RPG gas system 300B further comprises divert valve 303 in second RPG gas line 308B. Flow of the purge gas during an ALD process is controlled by divert valve 303 instead of mass flow controller 314B. Reactant gas flow also may be controlled by a mass flow controller (not shown) along first RPG gas line 306B.

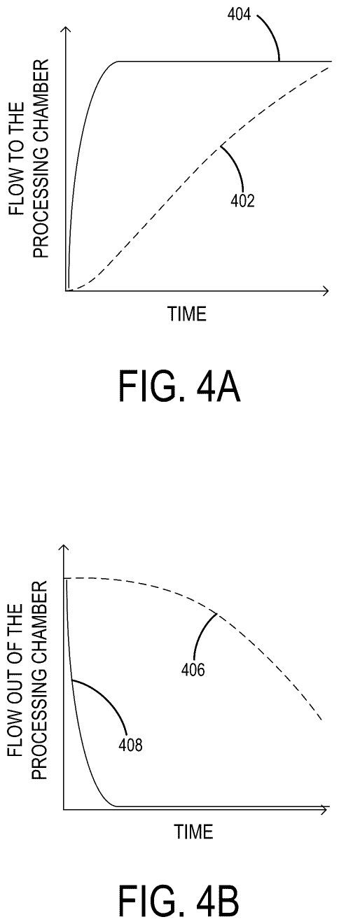

FIG. 4A shows a plot of reactant gas flow to a processing chamber as a function of time for RPG gas system 300A and RPG gas system 300B. Plot 402 is for RPG gas system 300A, in which mass flow controller 314A is used to control purge gas flow rate to processing chamber 304A. Plot 404 is for RPG gas system 300B, in which divert valve 303 is used to control purge gas flow to processing chamber 304B while mass flow controller 314B maintains a set flow. Plot 402 in FIG. 4A shows a relatively greater time lag. This time lag represents the time taken for purge gas to reach the processing chamber after the mass flow controller 314A in FIG. 3A is turned on. The time lag may increase if the mass flow controller 314A is moved further upstream from processing chamber 304A. In contrast, referring to plot 404, the time lag is relatively lower for the use of divert valve 303 in RPG gas system 300B. Placing divert valve 303 and RPG gas manifold 302B physically closer to processing chamber 304B to shorten a gas line between these components may help to further reduce the time lag relative to the use of longer gas lines between these components.

Next, FIG. 4B shows a plot of purge gas flow out of a processing chamber as a function of time for RPG gas system 300A and RPG gas system 300B. Plot 406 is for RPG gas system 300A, in which mass flow controller 314A is used to control purge gas flow rate to processing chamber 304A. Plot 408 is for RPG gas system 300B, in which divert valve 303 is used to control purge gas flow to processing chamber 304B while mass flow controller 314B maintains a set flow. As shown, the use of divert valve 303 to control gas flows into the processing chamber may provide for faster chamber evacuation after purging due to the faster response of divert valve 303 compared to a mass flow controller.

In an ALD process, purge gas flow can be turned on and off multiple times. Where a mass flow controller alone is used to control purge gas flow, the ramp up and ramp down times as shown by plots 402 and 406 may comprise a significant percentage of the ALD cycle time. In contrast, the additional use of a divert valve to control purge gas flow, may provide for faster ramp up and ramp down times as shown by plots 404 and 408. This may decrease overall ALD processing time and help to increase tool throughput.

Switching precursor flows to a chamber on and off also can impact overall ALD processing times. As mentioned above, a precursor is adsorbed to a substrate surface in an ALD process. Excess precursor is then purged from the process chamber. After purging, precursor that is adsorbed to the substrate surface is chemically converted to a film on the substrate surface by a reactant. In some examples, a precursor can comprise a liquid phase chemical with a vapor pressure. In such examples, precursor vapor can be delivered to a processing chamber using a FOV delivery system. Referring briefly back to FIG. 1, a liquid phase precursor is held in ampoule 120. Precursor in ampoule 120 comprises a vapor pressure. Thus, precursor vapor can be carried to a FOV distribution system 130 using a carrier gas from carrier gas source 124.

However, cycling FOV precursor delivery on and off during an ALD process can cause delays. Some delays can arise from diameters of gas lines used in a FOV precursor delivery system. Other delays can arise from a volume of space within the FOV precursor delivery system. For example, gas lines of larger inner diameter can conduct a charge of precursor vapor to a processing chamber more slowly than gas lines of smaller inner diameter. Likewise, a dead volume in a FOV precursor delivery system also can slow precursor delivery.

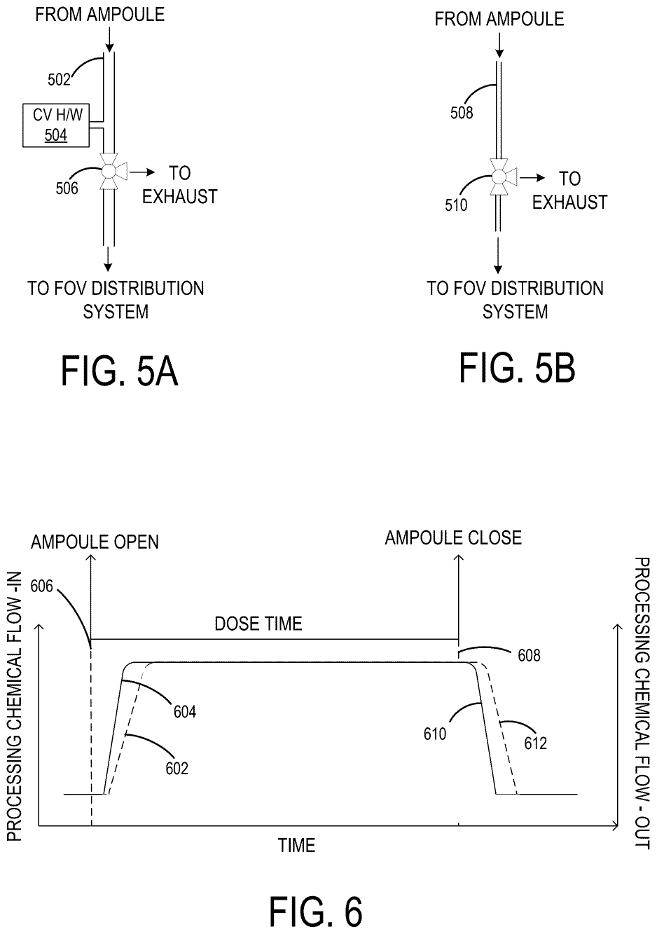

Thus, to reduce a lag time associated with switching a FOV precursor delivery system on and off between ALD cycles, inner diameters of gas lines may be reduced. Further, a FOV gas line may be modified to reduce dead volume. FIG. 5A schematically shows an example initial gas line 502 from an ampoule to a FOV distribution system. FIG. 5A also shows a charge volume hardware 504 and a divert valve 506. Charge volume hardware 504 represents hardware in a FOV distribution system that increases an internal volume of the system. In some examples, initial gas line 502 comprises an inner diameter of 0.305 inch or larger.

FIG. 5B schematically shows an example modification that replaces initial gas line 502 with an example replacement gas line 508. Replacement gas line 508 comprises an inner diameter that is smaller than the inner diameter of initial gas line 502. In some examples, replacement gas line 508 may comprise an inner diameter in the range of 0.110-0.430 inch. Replacement gas line 508 also has charge volume hardware 504 removed. FIG. 5B also shows a replacement divert valve 510. Replacement gas line 508 and/or replacement divert valve 510 can be used in a processing tool with the RPG gas manifold 200 of FIG. 2 in some examples. An example of such a processing tool is processing tool 100 of FIG. 1.

FIG. 6 shows example plots of FOV precursor flow as a function of time for initial gas line 502 and replacement gas line 508. Plot 602 corresponds to initial gas line 502. Plot 604 correspond to replacement gas line 508. The time when the ampoule is opened is marked at 606 and the time when the ampoule is closed is marked at 608. The time from 606 to 608 may be referred to as a dose time.

The relatively larger inner diameter of initial gas line 502 compared to replacement gas line 508 results in a longer delay before precursor flow starts to ramp in the process chamber after the ampoule is set to open 606, as shown at 602. Additionally, due to the charge volume hardware 504 as shown in FIG. 5A, the early part of the dose step may be diluted by the gas accumulation in that volume during the next step, which can contribute to the longer ramp time. In comparison, the relatively smaller inner diameter of replacement gas line 508 compared to initial gas line 502 results in a shorter delay before the flow starts to ramp in the process chamber after the ampoule is set to open 606, as shown at 604.

Likewise, the relatively smaller inner diameter of replacement gas line 508 results in a shorter pump down time, as shown at 610 in FIG. 6. In contrast, the relatively larger inner diameter of initial gas line 502, holds a relatively higher gas volume and thus can result in a relatively longer pump down time, as shown at 612 in FIG. 6. As such, the replacement of initial gas line 502 with replacement gas line 508 having a smaller inner diameter and reduced dead volume can result in less delay during an ALD process. This may help to increase throughput.

The above-described examples relate to decreasing an ALD cycle time by reducing delays that arise from stabilizing gas flows. An ALD cycle time alternatively or additionally may be reduced by increasing a residence time of precursor molecules and/or reactive species over a substrate. In some examples, a showerhead may comprise a purge gas outlet that creates purge gas flow in the form of a shroud at least partially around a substrate on a pedestal. Such a purge gas flow may impede precursor flow from over the substrate to an exhaust system. This may increase a residence time of the precursor and/or radical species over the substrate. The increased residence time may help to increase an efficiency of conversion of precursor to deposited film.

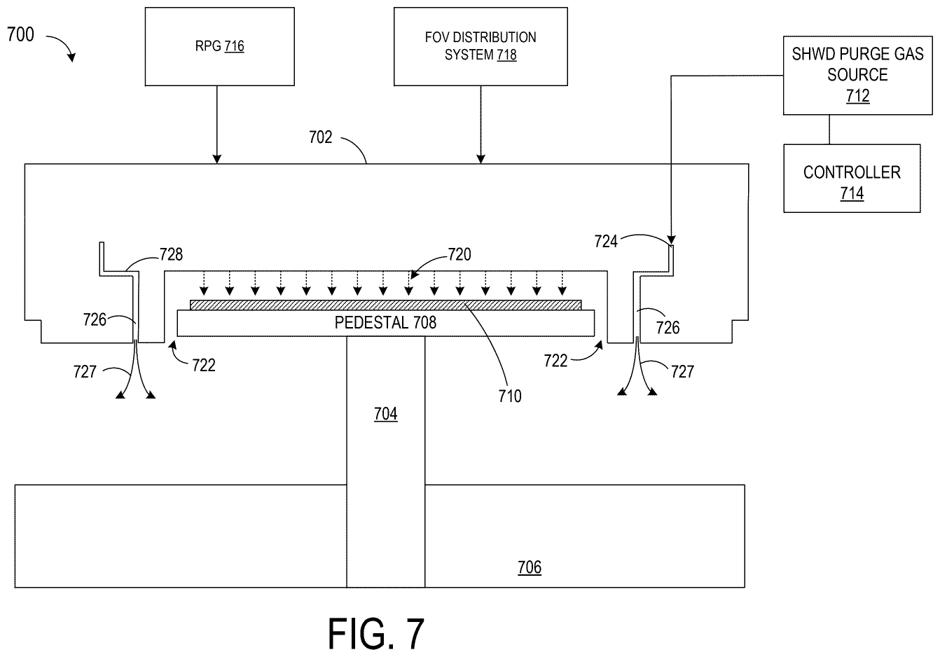

FIG. 7 schematically shows example processing tool components 700 for a processing tool. Processing tool components 700 can be incorporated in processing tool 100 of FIG. 1, for example. In some examples, processing tool components 700 can be used in a same tool as RPG gas manifold 200 of FIG. 2. Further, in some examples, processing tool components 700 can be used in a same processing tool as replacement gas line 508 and replacement divert valve 510 of FIG. 5B.

Processing tool components 700 comprise a showerhead 702. Processing tool components 700 further comprise a pedestal support 704 extending upwardly from a processing chamber base 706, and a pedestal 708 supporting a substrate 710.

Processing tool components 700 further comprise a showerhead purge gas source 712. Flow of purge gas from showerhead purge gas source 712 is controllable by a controller 714. Controller 714 is an example of controller 148 of FIG. 1.

Processing tool components 700 further comprises processing gas sources, illustrated as a remote plasma generator (RPG) 716 and a flow over vapor (FOV) distribution system 718. RPG 716 and FOV distribution system 718 are fluidly connected to showerhead 702 to provide processing gases to showerhead 702. Flows of processing gases from showerhead 702 toward substrate 710 are illustrated by arrows 720. Interior gas flow passages of showerhead 702 for delivering processing gases from RPG 716 and FOV distribution system 718 are omitted for clarity. RPG 716 can receive gas flows from RPG gas manifold 200 in some examples.

In a portion of an ALD cycle, precursor from FOV distribution system 718 adsorbs to substrate 710. In another portion of the ALD cycle, reactive species from RPG 716 react with precursor adsorbed to substrate 710. Unreacted precursor and radical species, along with reaction products, flow through opening 722 to an exhaust system. Purge cycles can be run between exposures of substrate 710 to precursor and reactive species.

To help increase a residence time of precursor and/or reactive species over substrate 710, purge gas from showerhead purge gas source 712 is directed through a showerhead purge gas outlet 726 disposed adjacent to a perimeter of showerhead 702. In the depicted example, showerhead purge gas flows through an inlet 724, and then through showerhead purge gas outlet 726. Arrows 727 illustrate showerhead purge gas flow. A plenum 728 distributes the showerhead purge gas flow so that the showerhead purge gas flows through different locations of showerhead purge gas outlet 726 at suitably even flow rates. In other examples, a showerhead purge gas outlet can be in a different location than showerhead purge gas outlet 726. Example purge gases can include inert gases such as helium and argon.

The purge gas can exert a back pressure on gas flow through opening 722. This may slow gas flow through opening 722, and thereby increase the residence time of the processing chemical over the substrate 710. The residence time of precursor and reactive species over substrate 710 may be varied by controlling a relative flow of the purge gas to flows of precursor and/or a flow containing reactive species from an RPG.

In some examples, showerhead purge gas outlet 726 can be annular and continuous. In other examples, a plurality of showerhead purge gas outlets can be distributed around a showerhead. In the depicted example, showerhead purge gas outlet 726 is directed vertically downwardly. In other examples, one or more showerhead purge gas outlets can direct purge gas flow towards the pedestal support 704. In further examples, one or more showerhead purge gas outlets may direct purge gas flow away from the pedestal support 704.

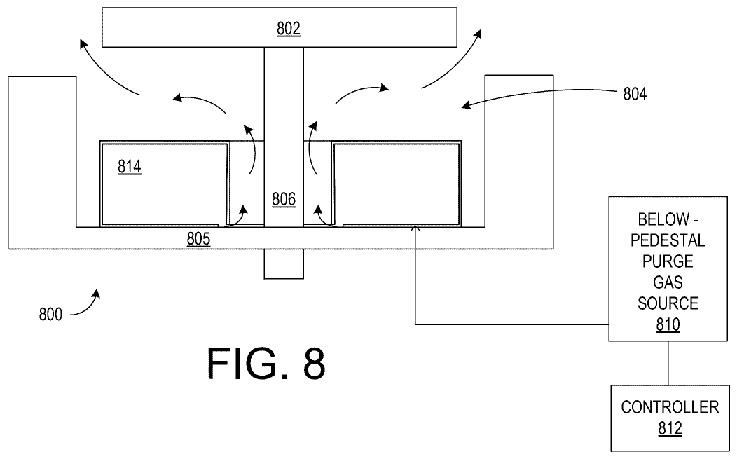

A similar back pressure effect on gas flow through opening 722 can be achieved by use of a below-pedestal purge system. FIG. 8 illustrates such a below-pedestal purge system. More particularly, FIG. 8 shows example processing tool components 800 of a processing tool. Processing tool components 800 can be incorporated in processing tool 100 of FIG. 1, for example. In some examples, processing tool components 800 can be used in a same tool as RPG gas manifold 200 of FIG. 2. Further, in some examples, processing tool components 800 can be used in a same processing tool as replacement gas line 508 and replacement divert valve 510 of FIG. 5B. Also, in some examples, processing tool components 800 be used in a same processing tool as showerhead purge gas outlet 726 of FIG. 7.

Processing tool components 800 comprise a pedestal 802 within a pedestal well 804 formed by a chamber base 805, and a pedestal support 806. Processing tool 800 components also comprise a below-pedestal plenum 814 within pedestal well 804. Below-pedestal plenum 814 comprises an interior to accommodate a purge gas, and a purge gas outlet arranged at a lower portion of below-pedestal plenum 814. Arrows indicate purge gas flow from below-pedestal plenum 814. A below-pedestal purge gas source 810 provides purge gas to the below-pedestal plenum 814. A controller 812 controls purge gas flow. For example, controller 812 may control a mass flow controller or other flow controller of below-pedestal purge gas source 810.

Purge gas flow from below-pedestal plenum 814 may help to create a back pressure effect to increase precursor and/or reactive species residence time above a substrate. This may help to decrease a time taken to perform an ALD cycle. Further, pedestal well 804 comprises a volume of space beneath pedestal 802. Unreacted precursor and reaction products can diffuse to pedestal well 804 during a deposition process. Thus, purge gas flow from below-pedestal plenum 814 helps to purge such species from pedestal well 804. Below-pedestal plenum 814 also helps to fill volume in pedestal well 804. This reduces a volume of space to be purged. This further may help to reduce a time taken to purge a processing chamber between ALD steps. The below-pedestal purge gas may comprise any suitable gas that does not react with species or surfaces exposed to the purge gas. Example purge gases comprise argon.

In the depicted example, below-pedestal plenum 814 comprises an annular structure with one or more openings arranged at a lower portion of the below-pedestal plenum 814. Purge gas flows towards the pedestal support 806 and into the pedestal well 804. A height of below-pedestal plenum 814 may vary in different examples. The use of a taller below-pedestal plenum 814 may reduce the open volume within pedestal well 804. This may help to shorten the duration of purge steps in an ALD cycle. A height of below-pedestal plenum 814 can be selected to accommodate a desired range of pedestal height adjustment.

The opening in below-pedestal plenum 814 may take various different forms. In some examples, a below-pedestal plenum 814 may comprise a single opening extending around the below-pedestal plenum. In other examples, a below-pedestal plenum may comprise multiple horizontal openings with either the same or different sizes. In further examples, a below-pedestal plenum may comprise multiple vertical openings with either the same or different sizes. In yet further examples, a below-pedestal plenum may comprise an array of holes. The size and the shape of the holes may vary.

In the example of FIG. 8, below-pedestal plenum 814 has a vertical interior wall with an opening at a bottom region through which purge gas flows. In other examples, a below-pedestal plenum may have any other suitable configuration. For example, a below-pedestal plenum may have a diagonally oriented wall and/or a curved wall. Likewise, a below pedestal-plenum may have openings of any suitable shape or shapes.

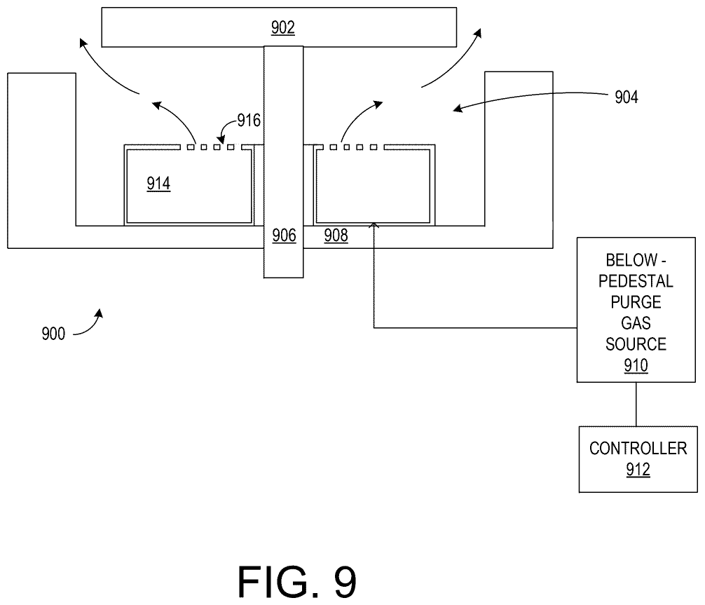

FIG. 9 illustrates another example of a below-pedestal purge system. More particularly, FIG. 9 shows processing tool components 900 of an example processing tool. Processing tool components 900 can be incorporated in processing tool 100 of FIG. 1, for example. In some examples, processing tool components 900 can be used in a same tool as RPG gas manifold 200 of FIG. 2. Further, in some examples, processing tool components 900 can be used in a same processing tool as replacement gas line 508 and replacement divert valve 510 of FIG. 5B. Also, in some examples, processing tool components 900 be used in a same processing tool as showerhead purge gas outlet 726 of FIG. 7.

Processing tool components 900 comprise a pedestal 902 within a pedestal well 904, a pedestal support 906, and a processing chamber base 908 that defines pedestal well 904. Processing tool components 900 also comprise a below-pedestal plenum 914 within pedestal well 904. Below-pedestal plenum 914 comprises an interior to accommodate a purge gas, and a plurality of purge gas outlets indicated by dashed lines and gas flow arrows. Below-pedestal purge gas source 910 provides purge gas to the below-pedestal plenum 914. A controller 912 controls purge gas flow. For example, controller 912 may control a mass flow controller or other flow controller of below-pedestal purge gas source 910.

Below-pedestal plenum 914 comprises openings 916 facing pedestal 902, rather than an interior side facing pedestal support 906. The flow of purge gas may create a back pressure effect to increase precursor residence time above a substrate, as described above. This may increase an efficiency of precursor use and also shorten precursor exposure times.

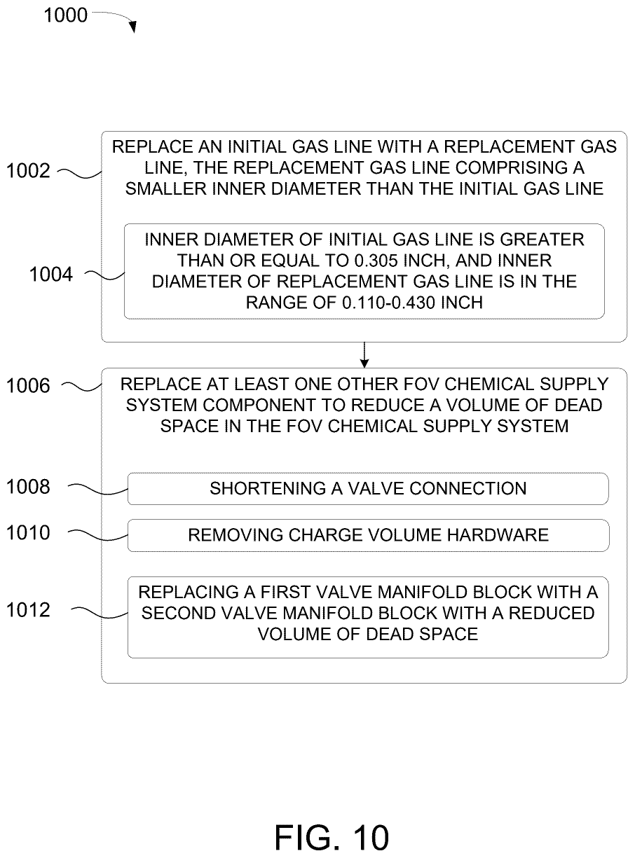

As described above with regard to FIGS. 5A, 5B and 6, a ramp up and ramp down time for a precursor flow into and out of a processing chamber may be shortened by modifying a gas flow line used to deliver the precursor. FIG. 10 shows a flow diagram depicting an example method 1000 of modifying a FOV chemical supply system. Method 1000 comprises replacing an initial gas line with a replacement gas line at step 1002. The replacement gas line has a smaller inner diameter than the initial gas line. In some examples, as indicated at 1004, the initial gas line comprises an inner diameter greater than or equal to 0.305 inch, and the replacement gas line comprises an inner diameter in the range of 0.110-0.430 inch. The use of a smaller inner diameter gas line may decrease a time that elapses between opening a FOV chemical supply system valve and FOV chemical reaching the processing chamber. This may reduce ALD cycle time and increase throughput.

Modifying the FOV chemical supply system at step 1002 further may comprise, at step 1006, replacing at least one other FOV chemical supply system component to reduce a volume dead volume in the FOV chemical supply system. Reducing dead volume may reduce the time it takes for the FOV chemical to reach the processing chamber. This is because the time taken to fill the dead volume is eliminated. Reducing dead volume also may help to avoid transient dilution of the FOV chemical, which can be a precursor in an ALD process.

Valve connections may comprise dead volume. Thus, in some examples, method 1000 may comprise, at step 1008, shortening a valve connection. This may comprise, for example, replacing a first valve with a second valve with a lower dead volume.

Method 1000 further may comprise, at step 1010, removing a charge volume hardware. Removing the charge volume hardware reduces a total the volume of the gas line. This reduces the time taken for the FOV chemical to reach the processing chamber. Further, removing charge volume hardware may also help to avoid dilution in an early part of a FOV chemical introduction step arising from gas in the charge volume hardware.

Further, in some examples, modifying a FOV chemical supply system may comprise, at step 1012, replacing a first valve manifold with a second valve manifold that comprises a reduced dead volume. As discussed earlier, a valve manifold may comprise one or more valves, one or more tees and associated fittings. In some examples, valves for serviceability of a processing tool, along with the associated fittings, may be reduced or eliminated. In other examples, valves for sampling or measurements of the FOV chemical in the FOV chemical supply system, along with the associated fittings, may be reduced or eliminated. In yet other examples, tees, bends and other fittings may be reduced or eliminated to reduce the dead volume. In other examples, one or more valves may be replaced with valves comprising of reduced dead volume inside the valve assembly.

Method 1000 can be used to incorporate modified gas line 508 and/or replacement divert valve 510 into a processing tool, such as processing tool 100 of FIG. 1. Further, method 1000 can be performed on a processing tool that comprises RPG gas manifold 200, replacement gas line, and/or replacement divert valve 510. Also, in some examples, method 1000 can be performed on a processing tool that comprises a showerhead purge gas outlet such as that shown in FIG. 7. Further, in some examples, method 1000 can be performed on a same processing tool that comprises a below-pedestal purge system, such as those shown in FIGS. 8 and 9.

It will be understood that the configurations and/or approaches described herein are exemplary in nature, and that these specific embodiments or examples are not to be considered in a limiting sense, because numerous variations are possible. The specific routines or methods described herein may represent one or more of any number of processing strategies. As such, various acts illustrated and/or described may be performed in the sequence illustrated and/or described, in other sequences, in parallel, or omitted. Likewise, the order of the above-described processes may be changed.

The subject matter of the present disclosure includes all novel and non-obvious combinations and sub-combinations of the various processes, systems and configurations, and other features, functions, acts, and/or properties disclosed herein, as well as any and all equivalents thereof.

1. A processing tool, comprising:
a processing chamber;
a remote plasma generator (RPG) fluidly connected to the processing chamber; and
an RPG gas supply system for mixing and delivering gases to the RPG, the RPG gas supply system comprising:
a first RPG gas line for delivering a first gas at a first flow rate to the RPG;
a second RPG gas line for delivering a second gas at a second flow rate to the RPG, the second flow rate higher than the first flow rate;
a junction connecting the first RPG gas line and the second RPG gas line;
an orifice in the first RPG gas line;
a divert valve on the second RPG gas line for diverting a flow away from the RPG; and
a common RPG gas line connecting the junction to the RPG.

2. The processing tool of claim 1, wherein the second RPG gas line comprises a mass flow controller upstream of the junction connecting the first RPG gas line and the second RPG gas line.

3. The processing tool of claim 1, wherein the first RPG gas line is connected to a hydrogen gas source and a nitrogen gas source.

4. The processing tool of claim 1, wherein the second RPG gas line is connected to a nitrogen gas source.

5. The processing tool of claim 1, wherein the processing chamber comprises a showerhead and a pedestal, and the showerhead comprises a showerhead purge gas outlet disposed adjacent to a perimeter of the showerhead.

6. The processing tool of claim 5, further comprising a controller configured to control a flow of inert gas through the showerhead purge gas outlet during a deposition process.

7. The processing tool of claim 6, further comprising
a pedestal, and
a below-pedestal purge system comprising one or more openings to flow a purge gas into the processing chamber beneath the pedestal.

8. The processing tool of claim 7, further comprising a controller configured to control a flow of inert gas through the below-pedestal purge system during a deposition process.

9. The processing tool of claim 1, wherein the processing tool comprises a flow over vapor (FOV) chemical supply system for delivering a processing chemical to the processing chamber, the FOV chemical supply system comprising a processing chemical delivery gas line comprising an inner diameter in a range of 0.110-0.430 inch.

10. A processing tool, comprising:
a processing chamber comprising a pedestal well;
a pedestal positioned at least partially within the pedestal well; and
a below-pedestal purge system configured to introduce a flow of a purge gas into the pedestal well beneath the pedestal.

11. The processing tool of claim 10, wherein the below-pedestal purge system comprises a below-pedestal plenum arranged at least partially around a pedestal support of the pedestal, the below-pedestal plenum comprising one or more openings to flow the purge gas into the processing chamber from beneath the pedestal.

12. The processing tool of claim 11, wherein the below-pedestal plenum is annular in shape.

13. The processing tool of claim 11, wherein the below-pedestal plenum comprises a plurality of openings.

14. The processing tool of claim 11, wherein the below-pedestal plenum is additively manufactured.

15. The processing tool of claim 10, further comprising a showerhead, the showerhead comprising a showerhead purge gas outlet.

16. A method of modifying a processing tool, the processing tool comprising a processing chamber and a flow over vapor (FOV) chemical supply system for delivering a processing chemical to the processing chamber, the FOV chemical supply system comprising a gas line for processing chemical delivery to the processing chamber, the method comprising:
replacing an initial gas line with a replacement gas line, the replacement gas line comprising a smaller inner diameter than the initial gas line, thereby decreasing a time that elapses between opening a FOV chemical supply system valve and FOV chemical reaching the processing chamber, and
replacing at least one other FOV chemical supply system component to reduce a dead volume in the FOV chemical supply system.

17. The method of claim 16, wherein the initial gas line comprises an inner diameter of greater than or equal to 0.305 inch, and the replacement gas line comprises an inner diameter in the range of 0.110-0.430 inch.

18. The method of claim 16, wherein replacing at least one other FOV chemical supply system component comprises shortening a valve connection.

19. The method of claim 16, wherein replacing at least one other FOV chemical supply system component comprises removing a charge volume hardware.

20. The method of claim 16, wherein replacing at least one other FOV chemical supply system component comprises replacing a first valve manifold with a second valve manifold with a reduced dead volume.
